(19) United States
(12) Patent Application Publication
(10) Pub. No.: US 2013/0112845 A1
(43) Pub. Date: May 9, 2013

(54) MOUNTING APPARATUS FOR DATA STORAGE DEVICE

(71) Applicant: HAI-TAO GONG, Shenzhen City (CN)

(72) Inventor: HAI-TAO GONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/537,399

(22) Filed: Jun. 29, 2012

(30) Foreign Application Priority Data
Nov. 9, 2011 (CN) 201110351747.8

(51) Int. Cl. H05K 7/14

(52) U.S. Cl. 248/636

(57) ABSTRACT

A mounting apparatus includes a bracket, a data storage device and a vibration absorbing module. A slot is defined in the bracket. The data storage device comprises a sidewall with a locking hole. The vibration absorbing module is accommodated in the slot. The vibration absorbing module includes a fixing member and a vibration absorbing member. The fixing member is screwed into the locking hole. The vibration absorbing member is set on the fixing member. The vibration absorbing includes a blocking board and a plurality of buffering pieces. The plurality of buffering pieces is connected to edges of the blocking board and elastically deformability abut edges of the slot.

### BACKGROUND

1. Technical Field

The present disclosure relates to mounting apparatuses, and particularly to a mounting apparatus for a data storage device.

2. Description of Related Art

In a computer or server, a data storage device, such as a hard disk drive, a floppy disk drive, and a CD-ROM drive, is simply screwed to a computer enclosure. This mounting means is very complex, difficult and time-consuming. In addition, in use, vibration of the data storage device may cause the screws to come loose and may result in damage to the data storage device.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and a data storage device.

FIG. 2 is an exploded view of a vibration absorbing module of FIG. 1.

FIG. 3 is an assembled view of the vibration absorbing module of FIG. 2.

FIG. 4 is an assembled view of the mounting apparatus and the data storage device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

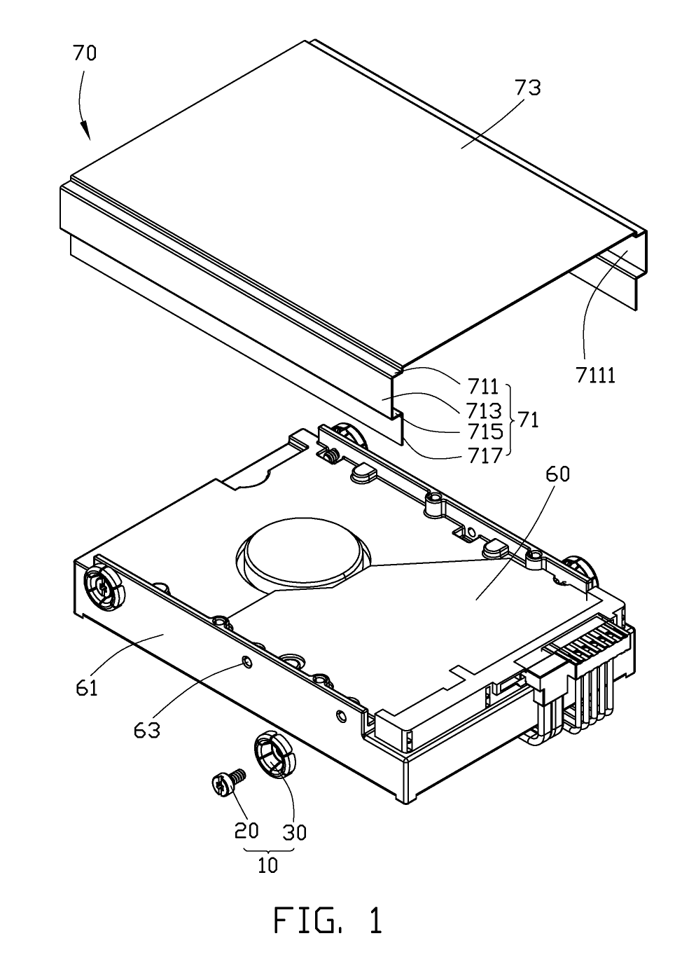

Referring to FIG. 1, a mounting apparatus, configured to secure a data storage device, includes a plurality of vibration absorbing modules 10 and a bracket 70.

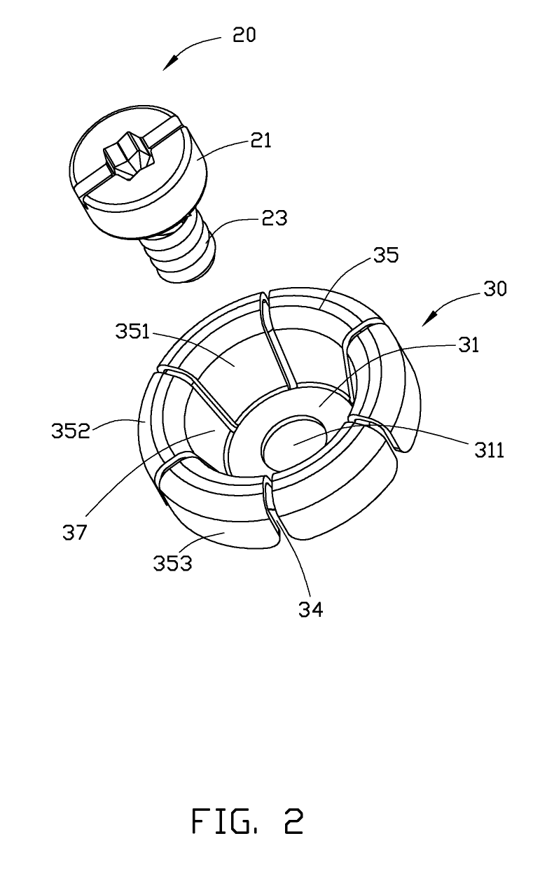

Each of the plurality of vibration absorbing modules 10 includes a fixing member 20 and a vibration absorbing member 30. Referring to FIG. 2, the fixing member 20 includes a head portion 21 and a pole portion 23. A thread is located on outer surface of the pole portion 23.

Referring to FIG. 2, the vibration absorbing member 30 includes a blocking board 31 and a plurality of buffering pieces 35. The blocking board 31 is substantially circular. A through hole 311 is defined in a center of the blocking board 31. In one embodiment, the through hole 311 is circular, a cross-section of the pole portion 23 is circular, a cross-section of the head portion 21 is circular; and a diameter of the through hole 311 is greater than a diameter of the cross-section of the pole portion 23 and smaller than a diameter of the cross-section of the head portion 21. The plurality of buffering pieces 35 are equidistantly located on edges of the blocking board 31. A gap 34 is defined between two adjacent buffering pieces 35. Each of the plurality of buffering pieces 35 includes a connecting portion 351, a bending portion 352, and a buffering portion 353. The connecting portion 351 tilts to connect the edge of the blocking board 31. In one embodiment, an obtuse angle is defined between the connecting portion 351 and the blocking board 31. The bending portion 352 is bent outward from a distal end of the connecting portion 351. The buffering portion 353 extends downwards from a distal end of the bending portion 352. In one embodiment, the buffering portion 353 is substantially parallel to the connecting portion 351, and each of the plurality of buffering pieces 35 is deformable. The blocking board 31 and the connecting portions 351 cooperatively define a retaining portion 37. The head portion 21 is capable of being accommodated in the retaining portion 37.

Referring to FIG. 1, the data storage device 60 includes two sidewalls 61. Each of the two sidewalls 61 defines a plurality of locking hole 63.

The bracket 70 includes a top panel 73 and two side panels 71 located on two opposite sides of the top panel 73. Each of the two side panels 71 includes a first portion 711, a second portion 713, a third portion 715, and a fourth portion 717. The first portion 711 is connected to the top panel 73. The second portion 713 extends downward from a distal end of the first portion 711. The third portion 715 extends inwards from a distal end of the second portion 713. The fourth portion 717 extends downwards from a distal end of the third portion 715. In one embodiment, the second portion 713 is substantially perpendicular to the first portion 711, the third portion 715 is substantially perpendicular to the second portion 713 and parallel to the first portion 711, and a fourth portion 717 is substantially perpendicular to the third portion 715 and parallel to the second portion 713. The first portion 711, the second portion 713, and the third portion 715 cooperatively define a slot 7111. In one embodiment, a width of the slot 7111 is greater than an outer diameter of the vibration absorbing member 30.

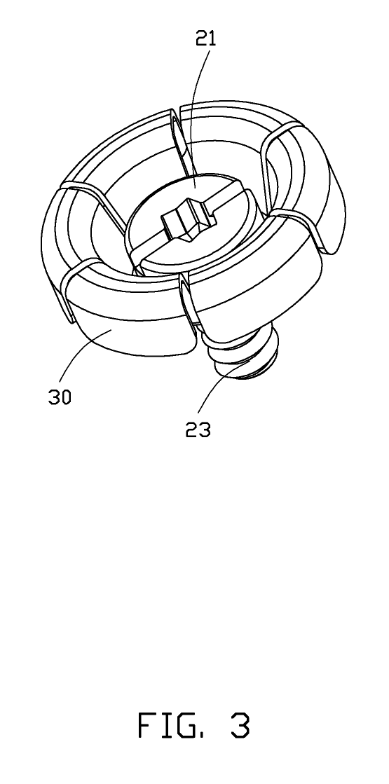

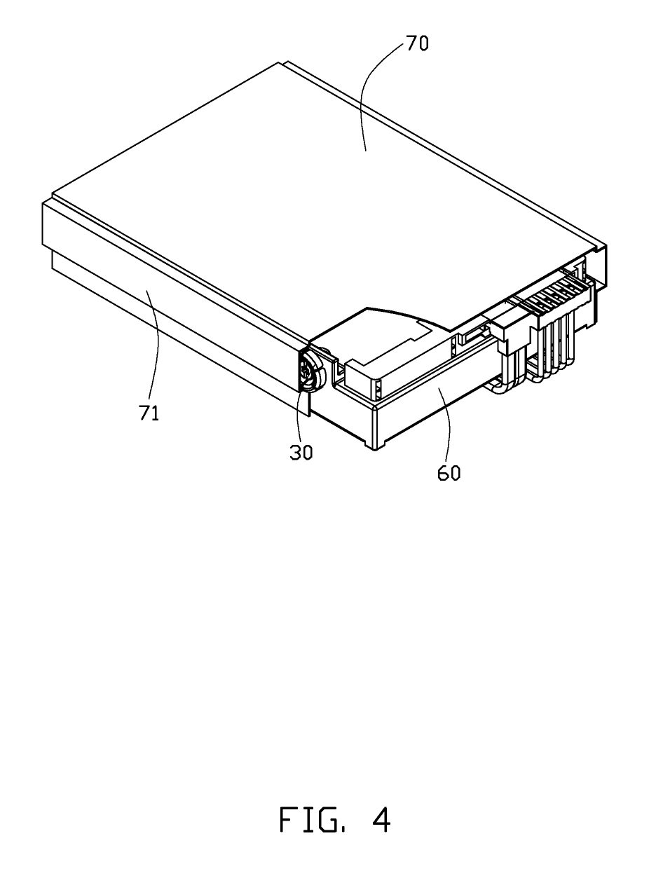

Referring to FIGS. 3 and 4, in assembly, the pole portion 23 of the fixing member 20 is inserted into the through hole 311. The head portion 21 is received in the retaining portion 37 and abuts the blocking board 31. The pole portion 23 is screwed into the locking hole 63 to secure one of the plurality of the vibration absorbing modules 10 to the data storage device 60. Each sidewall 61 has two vibration absorbing modules 10.

The data storage device 60 is pushed into the bracket 70. The vibration absorbing modules 10 slide into the slot 7111. The vibration absorbing members 30 elastically abut the first potion 711 and the third portion 715.

When the data storage device 60 is shocked relative to the bracket 70, the buffering portion 353 is elastically deformed along a direction perpendicular to an axial of the pole portion 23, to absorb vibration. The bending portions 352 is elastically deformed along a second direction parallel to the axial of the pole portion 23, to absorb vibration, and abut the second portion 713.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a bracket, a slot defined in the bracket; and
a vibration absorbing module accommodated in the slot, the vibration absorbing module comprising a fixing member and a vibration absorbing member; the fixing member configured to be engaged in a locking hole defined in a data storage device, the vibration absorbing member set on the fixing member, and the vibration absorbing member comprising a blocking board and a plurality of buffering pieces; the plurality of buffering pieces connected to edges of the blocking board and elastically deformable to abut edges of the slot.

2. The mounting apparatus of claim 1, wherein each of the plurality of buffering pieces comprises a connecting portion, a bending portion, and a buffering portion; the connecting portion is obliquely connected to the blocking board; the bending portion bends outwards from the connecting portion; and the buffering portion extends upwards from the bending portion.

3. The mounting apparatus of claim 2, wherein the buffering portion is substantially parallel to the connecting portion.

4. The mounting apparatus of claim 2, wherein the blocking board defines a through hole, the fixing member comprises a head portion and a pole portion, the pole portion extends through the through hole to be engaged in the locking hole defined in the data storage device, and the head portion abuts the blocking board.

5. The mounting apparatus of claim 4, wherein the through hole is circular, a cross-section of the pole portion is circular, a cross-section of the head portion is circular; and a diameter of the through hole is greater than a diameter of the cross-section of the pole portion and smaller than a diameter of the cross-section of the head portion.

6. The mounting apparatus of claim 4, wherein the connecting portion of the plurality of buffering pieces and the blocking board cooperatively define a retaining portion, and the head portion is accommodated in the retaining portion.

7. The mounting apparatus of claim 1, wherein the plurality of buffering pieces are equidistantly located on the edges of the blocking board, and a gap is defined in adjacent buffering pieces.

8. The mounting apparatus of claim 2, wherein the bracket comprises a side panel, the side panel comprises a first portion, a second portion, and a third portion, and the first portion, the second portion and the third portion cooperatively define the slot.

9. The mounting apparatus of claim 8, wherein the connecting portion of the plurality of buffering pieces elastically abut the first portion and the third portion, and the bending portion abuts the second portion.

10. The mounting apparatus of claim 8, wherein the first portion is substantially parallel to the third portion and perpendicular to the second portion.

11. A mounting apparatus comprising:
a bracket, a slot defined in the bracket; and
a vibration absorbing module accommodated in the slot, the vibration absorbing module comprising a fixing member and a vibration absorbing member; the fixing member configured to be engaged in a locking hole defined in a data storage device, the vibration absorbing member set on the fixing member, and the vibration absorbing member comprising a blocking board and a plurality of buffering pieces; each of the plurality of buffering pieces comprising a connecting portion, a bending portion, and a buffering portion, the connecting portion obliquely connected to the blocking board, the bending portion extending outwards from the connecting portion, the buffering portion extending upwards from the bending portion and elastically abut edges of the slot.

12. The mounting apparatus of claim 11, wherein the buffering portion is substantially parallel to the connecting portion.

13. The mounting apparatus of claim 11, wherein an obtuse angle is defined between the blocking board and the connecting portion.

14. The mounting apparatus of claim 11, wherein the blocking board defines a through hole, the fixing member comprises a head portion and a pole portion, the pole portion extends through the through hole and is configured to be engaged in the locking hole defined in the data storage device, and the head portion abuts the blocking board.

15. The mounting apparatus of claim 14, wherein the through hole is circular, a cross-section of the pole portion is circular, a cross-section of the head portion is circular;
and a diameter of the through hole is greater than a diameter of the cross-section of the pole portion and smaller than a diameter of the cross-section of the head portion.

16. The mounting apparatus of claim 14, wherein the connecting portion of the plurality of buffering pieces and the blocking board cooperatively define a retaining portion, and the head portion is accommodated in the retaining portion.

17. The mounting apparatus of claim 11, wherein the plurality of buffering pieces are equidistantly located on the edges of the blocking board, and a gap is defined in adjacent buffering pieces.

18. The mounting apparatus of claim 11, wherein the bracket comprises a side panel, the side panel comprises a first portion, a second portion, and a third portion, and the first portion, the second portion and the third portion cooperatively define the slot.

19. The mounting apparatus of claim 18, wherein the connecting portion of the plurality of buffering pieces elastically abut the first portion and the third portion, and the bending portion abuts the second portion.

20. The mounting apparatus of claim 18, wherein the first portion is substantially parallel to the third portion and perpendicular to the second portion.
